(19) United States
(12) Patent Application Publication
(10) Pub. No.: US 2014/0166472 A1
(43) Pub. Date: Jun. 19, 2014

(54) Method and apparatus for temperature control to improve low emissivity coatings

(71) Applicant: INTERMOLECULAR INC., San Jose, CA (US)

(72) Inventors: Guowen Ding, San Jose, CA (US); Brent Boyce, Novi, MI (US); Mohd Fadzli Anwar Hassan, San Francisco, CA (US); Minh Huu Le, San Jose, CA (US); Zhi-Wen Wen Sun, Sunnyvale, CA (US); Yu Wang, San Jose, CA (US)

(73) Assignee: INTERMOLECULAR INC., San Jose, CA (US)

(21) Appl. No.: 13/714,767

(22) Filed: Dec. 14, 2012

(51) Int. Cl. C23C 14/34

(52) U.S. Cl. CPC C23C 14/34
USPC 204/192.26; 204/298.09

(57) ABSTRACT

A method for making low emissivity panels, comprising cooling the article before or during sputter depositing a coating layer, such as a seed layer or an infrared reflective layer. The cooling process can improve the quality of the infrared reflective layer, which can lead to better transmittance in visible regime, block more heat transfer from the low emissivity panels, and potentially can reduce the requirements for other layers, so that the overall performance, such as durability, could be improved.

### FIELD OF THE INVENTION

The present invention relates generally to films providing high transmittance and low emissivity, and more particularly to such films deposited on transparent substrates.

### BACKGROUND OF THE INVENTION

Sunlight control glasses are commonly used in applications such as building glass windows and vehicle windows, typically offering high visible transmission and low emissivity. High visible transmission can allow more sunlight to pass through the glass windows, thus being desirable in many window applications. Low emissivity can block infrared (IR) radiation to reduce undesirable interior heating.

In low emissivity glasses, IR radiation is mostly reflected with minimum absorption and emission, thus reducing the heat transferring to and from the low emissivity surface. Low emissivity, or low-e, panels are often formed by depositing a reflective layer (e.g., silver) onto a substrate, such as glass. The overall quality of the reflective layer, such as with respect to texturing and crystallographic orientation, is important for achieving the desired performance, such as high visible light transmission and low emissivity (i.e., high heat reflection). In order to provide adhesion, as well as protection, several other layers are typically formed both under and over the reflective layer. The various layers typically include dielectric layers, such as silicon nitride, tin oxide, and zinc oxide, to provide a barrier between the stack and both the substrate and the environment, as well as to act as optical fillers and function as anti-reflective coating layers to improve the optical characteristics of the panel.

One known method to achieve low emissivity is to form a relatively thick silver layer. However, as the thickness of the silver layer increases, the visible light transmission of the reflective layer is reduced, as is manufacturing throughput, while overall manufacturing costs are increased. Therefore, is it desirable to form the silver layer as thin as possible, while still providing emissivity that is suitable for low-e applications.

### SUMMARY OF THE DISCLOSURE

In some embodiments, the present invention discloses methods and apparatuses for making coated articles, comprising cooling the article before or during sputter depositing a coating layer, such as a seed layer or an infrared reflective layer. The present temperature control process can provide improved quality of the infrared reflective layer, which can lead to better transmittance in visible regime, block more heat transfer from both sides of coated articles, and reduce the requirements for other layer of the coated article, so that the overall performance, such as durability, could easily improve.

In some embodiments, the article can be cooled in a cooling station before bringing the article to a sputter deposition chamber for sputter deposition. For example, a transport mechanism, such as a conveyor, can transfer the article to a cooling station for a certain time, for the article to reach a certain temperature, or for the temperature of the article to be reduced a certain amount. Afterward, the article can be introduced to the sputter deposition chamber. Similar cooling processes in the deposition chamber can be used as in the cooling station, comprising conduction, convection, or other cooling processes such as blowing dry ice on the article.

In some embodiments, the present invention discloses systems with cooling capability for making a coated article. The system can comprise a transport mechanism to transport the article between chambers or stations, a cooling station for cooling the article, and one or more sputter deposition chambers for depositing layers on the article. The cooling station is preferably disposed between the sputter deposition chambers, for example, to ensure a consistent temperature of the article before being deposited. The cooling station can be disposed before critical deposition process, such as a seed layer deposition or an infrared reflective layer deposition, for example, to ensure an optimal quality of the coated article.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1A illustrates an exemplary thin film coating according to some embodiments of the present invention.

FIG. 1B illustrates a low emissivity transparent panel according to some embodiments of the present invention.

FIG. 2 illustrates an exemplary physical vapor deposition (PVD) system having cooling capability according to some embodiments of the present invention.

FIGS. 3A-3B illustrate other exemplary cooling assemblies in a deposition system according to some embodiments of the present invention.

FIG. 4 illustrates an exemplary deposition system comprising a cooling station according to some embodiments of the present invention.

FIGS. 5A-5C illustrate exemplary configurations for cooling stations according to some embodiments of the present invention.

FIGS. 6A-6B illustrate exemplary configurations of multiple depositions with cooling capability according to some embodiments of the present invention.

FIG. 7 illustrates an exemplary in-line deposition system according to some embodiments of the present invention.

FIGS. 8A-8B illustrate exemplary flow charts for sputtering coated layers according to some embodiments of the present invention.

FIGS. 9A-9B illustrate other exemplary flow charts for sputtering coated layers according to some embodiments of the present invention.

FIGS. 10A-10B illustrate other exemplary flow charts for sputtering coated layers according to some embodiments of the present invention.

FIG. 11 illustrates another exemplary flow chart for sputtering coated layers according to some embodiments of the present invention.

### DETAILED DESCRIPTION OF THE PREFERRED EMBODIMENTS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, the present invention discloses methods and apparatuses for making low emissivity panels, comprising cooling the panels before or during the deposition of a coating layer, such as a conductive material (such as silver, gold or copper) on seed or base layers such as ZnO, SnO or a metal alloy oxide. The panels can be cooled in a cooling station before bringing to a deposition station, or cooled during the transfer to the deposition station, or cooled within the deposition station before or during the deposition process.

In some embodiments, the present invention recognizes that for coated articles, the layers deposited at lower temperatures can have better quality than layers deposited at higher temperatures. The present invention further recognizes that even about 10 degree difference can lead to observable quality difference of the coated articles.

In some embodiments, the present invention discloses methods and apparatuses for making coated articles, comprising cooling or lowering, the temperature of the article before depositing a coated layer, such as a seed layer or a silver layer. The articles can be cooled to a temperature below about 40° C., or preferably between about 5 and about 30° C., and more preferably between about 10 and about 25° C. Alternatively, the temperature of the articles can be lowered by at least about 5° C., by at most about 30 or about 25° C., or preferably by between about 5 and about 25° C.

In some embodiments, the present invention discloses methods and apparatuses for making low emissivity panels which comprise a low resistivity thin infrared reflective layer comprising a conductive material such as silver, gold, or copper. The thin silver layer can be thinner than 10 nm, such as 7 or 8 nm. The silver layer can have low roughness, and is preferably deposited on a seed layer also having low roughness. The present low emissivity panels can have improved overall quality of the infrared reflective layer with respect to conductivity, physical roughness and thickness. For example, the methods allow for improved conductivity of the reflective layer such that the thickness of the reflective layer may be reduced while still providing desirably low emissivity.

In general, the reflective layer preferably has low sheet resistance, since low sheet resistance is related to low emissivity. In addition, the reflective layer is preferably thin to provide high visible light transmission. Thus in some embodiments, the present invention discloses methods and apparatuses to deposit a thin and highly conductive reflective layer, providing a coated layer with high visible transmittance and low infrared emissivity. The present methods can also maximize volume production, throughput, and efficiency of the manufacturing process used to form low emissivity panels.

In some embodiments, the present invention discloses an improved coated transparent panel, such as a coated glass, that has acceptable visible light transmission and IR reflection. The present invention also discloses methods of producing the improved, coated, transparent panels, which comprise specific layers in a coating stack.

The coated transparent panels can comprise a glass substrate or any other transparent substrates, such as substrates made of organic polymers. The coated transparent panels can be used in window applications such as vehicle and building windows, skylights, or glass doors, either in monolithic glazings or multiple glazings with or without a plastic interlayer or a gas-filled sealed interspace.

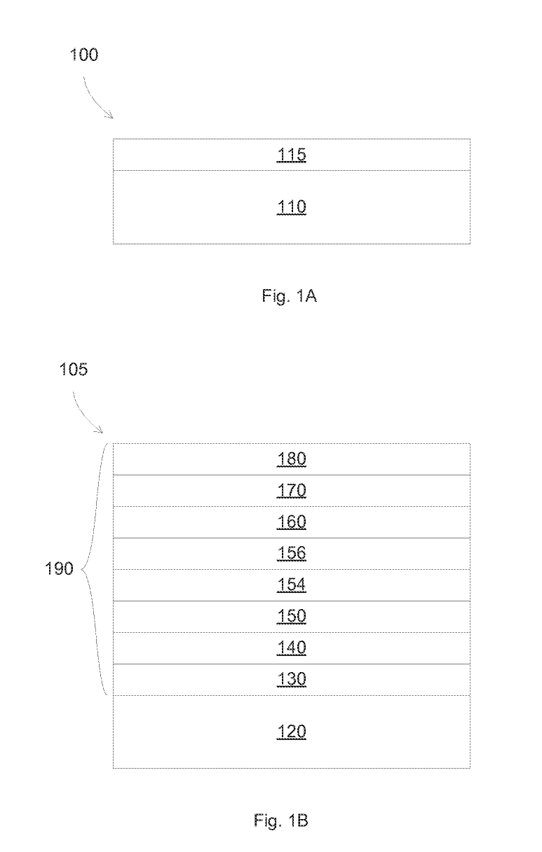

FIG. 1A illustrates an exemplary thin film coating according to some embodiments of the present invention. A smooth layer 115 is disposed on a substrate 110 to form a coated transparent panel 100, which has high visible light transmission, and low IR emission.

The layer 115 can be sputtered deposited using different processes and equipment, for example, the targets can be sputtered under direct current (DC), pulsed DC, alternate current (AC), radio frequency (RF) or any other suitable conditions. In some embodiments, the present invention discloses a physical vapor deposition method for depositing a smooth layer 115. In some embodiments, the method comprises limiting the distribution angle of the sputtered particles between the target and the substrate 110. For example, a screen, a shield or a collimator with holes can be used to restrict the direction of the sputtered particles that can reach the substrate. An example of a collimated sputtered system can be found in U.S. Pat. No. 5,330,628, which is incorporated by reference. The processing chamber can comprise a gas mixture introduced to a plasma ambient to sputter material from one or more targets disposed in the processing chamber. The sputtering process can further comprise other components such as magnets for confining the plasma, and utilize different process conditions such as DC, AC, RF, or pulsed sputtering.

In some embodiments, the smooth layer 115 can comprise a base layer, an oxide layer, a seed layer, a conductive layer, a barrier layer, an antireflective layer, or a protective layer. In some embodiments, the present invention discloses a high transmittance, low emissivity coated article comprising a transparent substrate, and a smooth metallic reflective film comprises one of silver, gold, or copper.

In some embodiments, the present invention discloses a coating stack, comprising multiple layers for different functional purposes. For example, the coating stack can comprise a seed layer to facilitate the deposition of the reflective layer, an oxygen diffusion layer disposed on the reflective layer to prevent oxidation of the reflective layer, a protective layer disposed on the substrate to prevent physical or chemical abrasion, or an antireflective layer to reduce visible light reflection. The coating stack can comprise multiple layers of reflective layers to improve IR emissivity.

FIG. 1B illustrates a low emissivity transparent panel 105 according to some embodiments of the present invention. The low emissivity transparent panel can comprise a glass substrate 120 and a low-e stack 190 formed over the glass substrate 120. The glass substrate 120 in one embodiment is made of a glass, such as borosilicate glass, and has a thickness of, for example, between 1 and 10 millimeters (mm). The substrate 120 may be square or rectangular and about 0.5-2 meters (m) across. In some embodiments, the substrate 120 may be made of, for example, plastic or polycarbonate.

The low-e stack 190 includes a lower protective layer 130, a lower oxide layer 140, a seed layer 150, a reflective layer 154, a barrier layer 156, an upper oxide 160, an optical filler layer 170, and an upper protective layer 180. Some layers can be optional, and other layers can be added, such as interface layer or adhesion layer. Exemplary details as to the functionality provided by each of the layers 130-180 are provided below.

The various layers in the low-e stack 190 may be formed sequentially (i.e., from bottom to top) on the glass substrate 120 using a physical vapor deposition (PVD) and/or reactive (or plasma enhanced) sputtering processing tool. In one embodiment, the low-e stack 190 is formed over the entire glass substrate 120. However, in other embodiments, the low-e stack 190 may only be formed on isolated portions of the glass substrate 120.

The lower protective layer 130 is formed on the upper surface of the glass substrate 120. The lower protective layer 130 can comprise silicon nitride, silicon oxynitride, or other nitride material such as SiZrN, for example, to protect the other layers in the stack 190 from diffusion from the substrate 120 or to improve the haze reduction properties. In some embodiments, the lower protective layer 130 is made of silicon nitride and has a thickness of, for example, between about 10 nm to 50 nm, such as 25 nm.

The lower oxide layer 140 is formed on the lower protective layer 130 and over the glass substrate 120. The lower oxide layer is preferably a metal or metal alloy oxide layer and can serve as an antireflective layer. An antireflective layer typically has index of refraction between those of the substrate and air. The lower metal oxide layer 140 may enhance the crystallinity of the reflective layer 154, as is described in greater detail below.

The layer 150 can be used to provide a seed layer for the IR reflective film, for example, a zinc oxide layer deposited before the deposition of a silver reflective layer can provide a silver layer with lower resistivity, which can improve its reflective characteristics. The seed layer can comprise a metal such as titanium, zirconium, and/or hafnium, or a metal alloy such as zinc oxide, nickel oxide, nickel chrome oxide, nickel alloy oxides, chrome oxides, or chrome alloy oxides.

In some embodiments, the seed layer 150 can be made of a metal, such as titanium, zirconium, and/or hafnium, and has a thickness of, for example, 50 Å or less. Generally, seed layers are relatively thin layers of materials formed on a surface (e.g., a substrate) to promote a particular characteristic of a subsequent layer formed over the surface (e.g., on the seed layer). For example, seed layers may be used to affect the crystalline structure (or crystallographic orientation) of the subsequent layer, which is sometimes referred to as “templating.” More particularly, the interaction of the material of the subsequent layer with the crystalline structure of the seed layer causes the crystalline structure of the subsequent layer to be formed in a particular orientation.

For example, a metal seed layer is used to promote growth of the reflective layer in a particular crystallographic orientation. In a particular embodiment, the metal seed layer is a material with a hexagonal crystal structure and is formed with a (002) crystallographic orientation which promotes growth of the reflective layer in the (111) orientation when the reflective layer has a face centered cubic crystal structure (e.g., silver), which is preferable for low-e panel applications.

In some embodiments, the crystallographic orientation can be characterized by X-ray diffraction (XRD) technique, which is based on observing the scattered intensity of an X-ray beam hitting the layer, e.g., silver layer or seed layer, as a function of the X-ray characteristics, such as the incident and scattered angles. For example, zinc oxide seed layer can show a pronounced (002) peak and higher orders in a θ-2θ diffraction pattern. This suggests that zinc oxide crystallites with the respective planes oriented parallel to the substrate surface are present.

In some embodiments, the terms “silver layer having (111) crystallographic orientation”, or “zinc oxide seed layer having (002) crystallographic orientation” comprise a meaning that there is a (111) preferred crystallographic orientation for the silver layer or a (002) preferred crystallographic orientation for the zinc oxide seed layer, respectively. The preferred crystallographic orientation can be determined, for example, by observing pronounced crystallography peaks in an XRD characterization.

In some embodiments, the seed layer 150 can be continuous and covers the entire substrate. Alternatively, the seed layer 150 may not be formed in a completely continuous manner. The seed layer can be distributed across the substrate surface such that each of the seed layer areas is laterally spaced apart from the other seed layer areas across the substrate surface and do not completely cover the substrate surface. For example, the thickness of the seed layer 150 can be a monolayer or less, such as between 2.0 and 4.0 Å, and the separation between the layer sections may be the result of forming such a thin seed layer (i.e., such a thin layer may not form a continuous layer).

The reflective layer 154 is formed on the seed layer 150. The IR reflective layer can be a metallic, reflective film, such as gold, copper, or silver. In general, the IR reflective film comprises a good electrical conductor, blocking the passage of thermal energy. In some embodiments, the reflective layer 154 is made of silver and has a thickness of, for example, 100 Å. Because the reflective layer 154 is formed on the seed layer 150, for example, due to the (002) crystallographic orientation of the seed layer 150, growth of the silver reflective layer 154 in a (111) crystalline orientation is promoted, which offers low sheet resistance, leading to low panel emissivity.

Because of the promoted (111) texturing orientation of the reflective layer 154 caused by the seed layer 150, the conductivity and emissivity of the reflective layer 154 is improved. As a result, a thinner reflective layer 154 may be formed that still provides sufficient reflective properties and visible light transmission. Additionally, the reduced thickness of the reflective layer 154 allows for less material to be used in each panel that is manufactured, thus improving manufacturing throughput and efficiency, increasing the usable life of the target (e.g., silver) used to form the reflective layer 154, and reducing overall manufacturing costs.

Further, the seed layer 150 can provide a barrier between the metal oxide layer 140 and the reflective layer 154 to reduce the likelihood of any reaction of the material of the reflective layer 154 and the oxygen in the lower metal oxide layer 140, especially during subsequent heating processes. As a result, the resistivity of the reflective layer 154 may be reduced, thus increasing performance of the reflective layer 154 by lowering the emissivity.

On the reflective layer 154 is a barrier layer 156, which can protect the reflective layer 154 from being oxidized. For example, the barrier can be a diffusion barrier, stopping oxygen from diffusing into the silver layer from the upper oxide layer 160. The barrier layer 156 can comprise titanium, nickel or a combination of nickel and titanium.

On the barrier layer 156 is an upper oxide layer, which can function as an antireflective film stack, including a single layer or multiple layers for different functional purposes. The antireflective layer 160 serves to reduce the reflection of visible light, selected based on transmittance, index of refraction, adherence, chemical durability, and thermal stability. In some embodiments, the antireflective layer 160 comprises tin oxide, offering highly thermal stability properties. The antireflective layer 160 can comprise titanium dioxide, silicon nitride, silicon dioxide, silicon oxynitride, niobium oxide, SiZrN, tin oxide, zinc oxide, or any other suitable dielectric material.

The optical filler 170 can be used to provide a proper thickness to the low-e stack, for example, to provide an antireflective property. The optical filler preferably has high visible light transmittance. In some embodiments, the optical filler layer 170 is made of tin oxide and has a thickness of, for example, 100 Å. The optical filler layer may be used to tune the optical properties of the low-e panel 105. For example, the thickness and refractive index of the optical filler layer may be used to increase the layer thickness to a multiple of the incoming light wavelengths, effectively reducing the light reflectance and improving the light transmittance.

An upper protective layer 180 can be used for protecting the total film stack, for example, to protect the panel from physical or chemical abrasion. The upper protective layer 180 can be an exterior protective layer, such as silicon nitride, silicon oxynitride, titanium oxide, tin oxide, zinc oxide, niobium oxide, or SiZrN.

In some embodiments, adhesion layers can be used to provide adhesion between layers. The adhesion layers can be made of a metal alloy, such as nickel-titanium, and have a thickness of, for example, 30 Å.

It should be noted that depending on the exact materials used, some of the layers of the low-e stack 190 may have some materials in common. An example of such a stack may use a zinc-based material in the oxide dielectric layers 140 and 160. As a result, a relatively low number of different targets can be used for the formation of the low-e stack 190.

In some embodiments, the coating can comprise a double or triple layer stack, having multiple IR reflective layers. In some embodiments, the layers can be formed using a plasma enhanced, or reactive sputtering, in which a carrier gas (e.g., argon) is used to eject ions from a target, which then pass through a mixture of the carrier gas and a reactive gas (e.g., oxygen), or plasma, before being deposited.

In some embodiments, the article can be cooled within a sputter deposition chamber that will perform the sputter deposition. For example, after introducing the article to the sputter deposition chamber, the article is cooled to a desired temperature before being coated with a sputtered layer. Alternatively, the substrate can be positioned on a cooled substrate support, e.g., a substrate support maintained at a certain temperature, which can prevent the substrate from being heated during the sputter deposition process. The cooling process can be performed by conduction, for example, by positioning the article on a cold plate. The cooling process can be performed by convection, for example, by position the article in high pressure ambient with cold flow. Other cooling processes can be performed, for example, by spraying with cold flow, such as cold air or dry ice on the article.

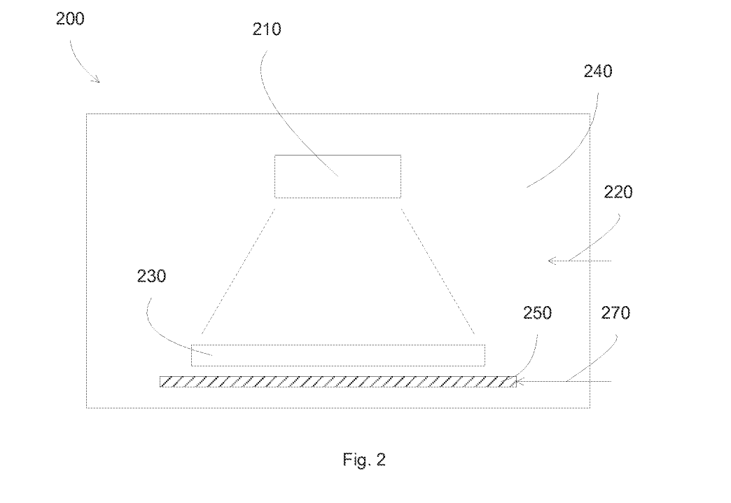

FIG. 2 illustrates an exemplary physical vapor deposition (PVD) system having cooling capability according to some embodiments of the present invention. The PVD system 200 includes a housing that defines, or encloses, a processing chamber 240, a substrate 230, a target assembly 210, and reactive species delivered from an outside source 220. During deposition, the target is bombarded with argon ions, which releases sputtered particles toward the substrate 230. A substrate cooling assembly 250 can be included to cool the substrate 230 before or during the sputter deposition process. The substrate cooling assembly 250 can comprise a cooling plate, with optional active cooling mechanism 270 to maintain the cooling plate at a desired temperature.

The materials used in the target 210 may, for example, include tin, zinc, magnesium, aluminum, lanthanum, yttrium, titanium, antimony, strontium, bismuth, silicon, silver, nickel, chromium, copper, gold, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides described above. Additionally, although only one target assembly 210 is shown, additional target assemblies may be used. As such, different combinations of targets may be used to form, for example, the dielectric layers described above. For example, in an embodiment in which the dielectric material is zinc-tin-titanium oxide, the zinc, the tin, and the titanium may be provided by separate zinc, tin, and titanium targets, or they may be provided by a single zinc-tin-titanium alloy target. For example, the target assembly 210 can comprise a silver target, and together with argon ions to sputter deposit a silver layer on substrate 230. The target assembly 210 can comprise a metal or metal alloy target, such as tin, zinc, or tin-zinc alloy, and together with reactive species of oxygen to sputter deposit a metal or metal alloy oxide layer.

The sputter deposition system 200 can comprise other components, such as a substrate support for supporting the substrate. The substrate support can comprise a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or dc bias to the substrate, or to provide a plasma environment in the process housing 240. The target assembly 210 can include an electrode which is connected to a power supply to generate a plasma in the process housing. The target assembly 210 is preferably oriented towards the substrate 230.

The sputter deposition system 200 can also comprise a power supply coupled to the target electrode. The power supply provides power to the electrodes, causing material to be, at least in some embodiments, sputtered from the target. During sputtering, inert gases, such as argon or krypton, may be introduced into the processing chamber 240 through the gas inlet 220. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 200 can also comprise a control system (not shown) having, for example, a processor and a memory, which is in operable communication with the other components and configured to control the operation thereof in order to perform the methods described herein.

In some embodiments, the present invention discloses methods and apparatuses for making thin low resistive silver layer, comprising limiting the temperature of the substrate, for example, due to the plasma heating, so that the deposition is performed at a low temperature, which can enable deposition of highly conductive silver layers. The substrate can be cooled, e.g., lowered to a predetermined temperature, before the deposition process starts. The substrate cooling assembly can maintain the substrate at a predetermined temperature during the deposition process. The substrate can be cooled to a temperature below about 40° C., or preferably between about 5 and about 30° C., and more preferably between about 10 and about 25° C. Alternatively, the temperature of the articles can be lowered by at least about 5° C., by about 30 or about 25° C., or preferably by between about 5 and about 25° C.

In some embodiments, the temperature of the substrate can increase during the low emissivity coating processes, for example, during the sputter deposition of the various layers. The temperature increase can be small, for example, 5 to 20° C., but this small temperature increase can have an effect on the resistivity of the silver conductive layer, especially at a thickness of less than 10 nm. Cooling the substrate, or reducing the temperature of the substrate, can improve the quality of the silver layer, and can offer panel consistency during the fabrication process.

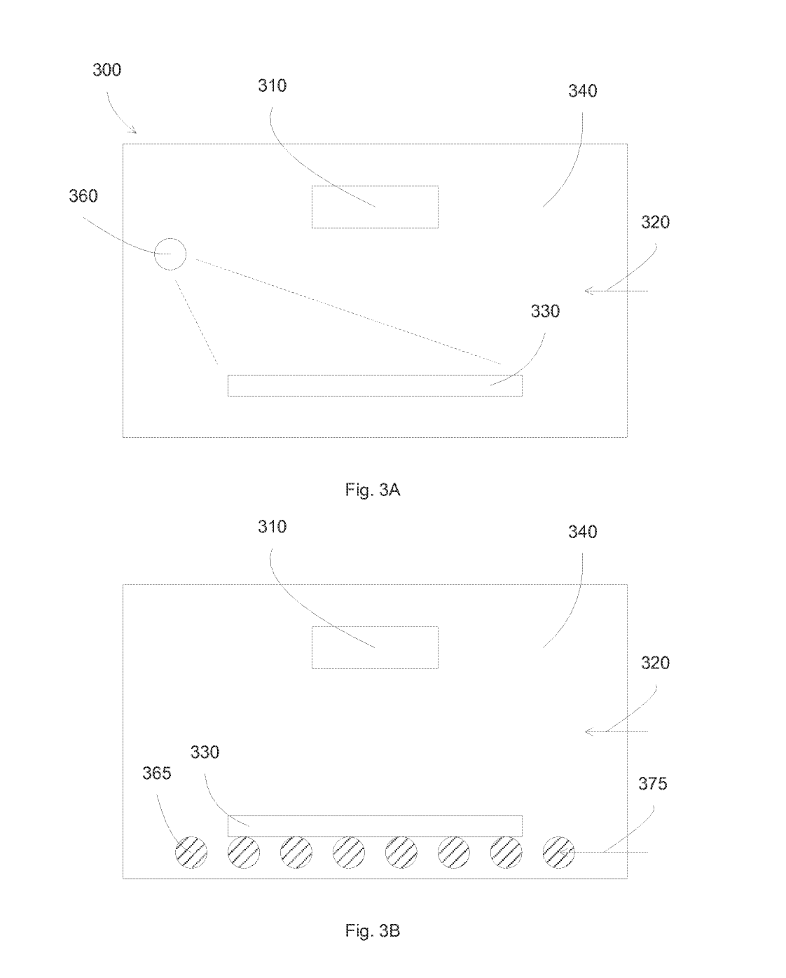

FIGS. 3A-3B illustrate other exemplary cooling assemblies in a deposition system according to some embodiments of the present invention. In FIG. 3A, a sputter deposition system 300 comprises a target assembly 310 disposed in a housing 340, containing reactive species delivered from an outside source 320. The target assembly 310 generally includes one or more materials that are to be used to deposit a layer of material on the upper surface of the substrate 330. A cooling assembly 360 can be added to cool the substrate. For example, the cooling assembly 360 can comprise delivering cold gas or particles such as dry ice (i.e., solid CO₂) to the substrate surface. The dry ice can cool the substrate without leaving residues on the substrate surface. In some embodiments, the cooling assembly 360 can cool the substrate after the substrate has been provided to the deposition system 300, and preferably before starting the deposition. In some embodiments, the cooling assembly 360 can be positioned near the entrance of the deposition system 300, and can cool the substrate during the transfer to the deposition system.

In FIG. 3B, a number of cooling rollers 365 can be used to cool the substrate, for example, during the transfer to the deposition system, or before or during the deposition. The rollers 365 can be actively cooled by a circulated coolant mechanism 375.

In some embodiments, a cooling station can be used to cool the substrate before being transferred to a sputter deposition chamber for sputter deposition. For example, a transport mechanism, such as a conveyor or rollers, can transfer the substrate to a cooling station to reach a certain temperature or to reduce the temperature of the substrate. Afterward, the substrate can be transferred to the sputter deposition chamber. Similar cooling processes in the deposition chamber can be used in the cooling station, comprising conduction, convection, cooling plate, cooling rollers, or other cooling processes such as delivering dry ice on the substrate.

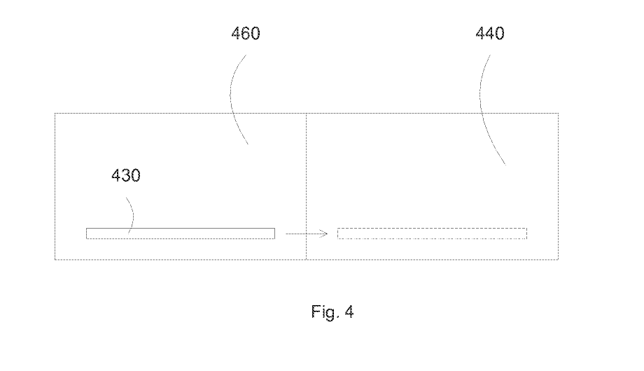

FIG. 4 illustrates an exemplary deposition system comprising a cooling station according to some embodiments of the present invention. A cooling station 460 is positioned before a sputter deposition system 440 for cooling the substrate 430 before reaching the deposition system. The substrate 430 can stop at the cooling station for a period of time so that the temperature of the substrate reaches a desired temperature or the temperature of the substrate reduces a desired value. For example, the cooling station 460 can keep the substrate at a temperature between 5 and 20° C., or the cooling station 460 can lower the substrate temperature between 10 and 30° C. relative to its initial temperature, thus providing optimized deposition coating due to the cool substrate.

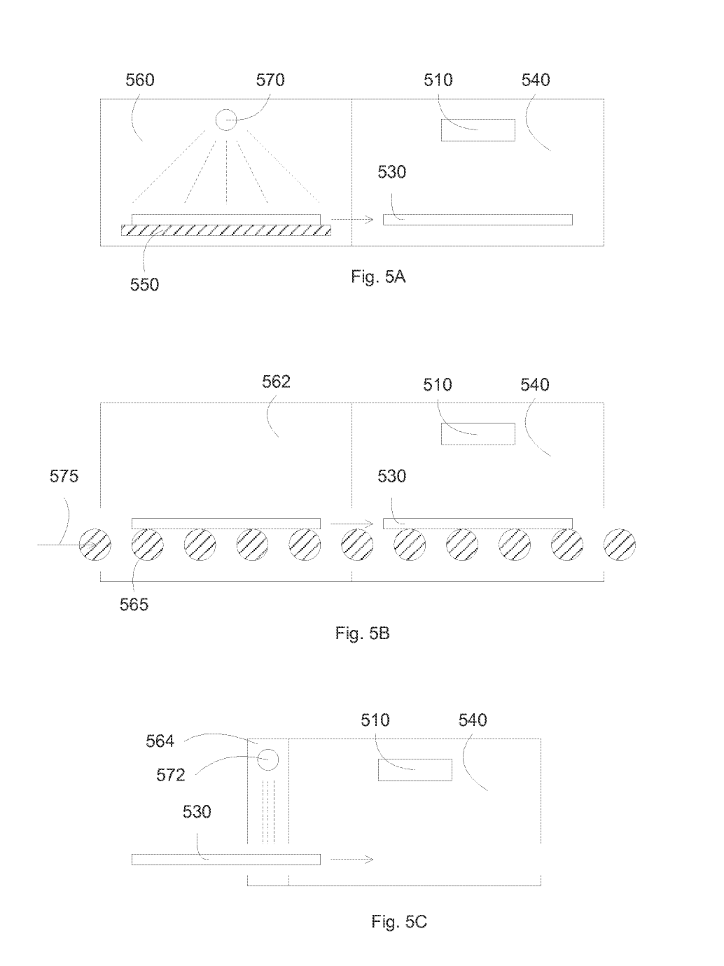

FIGS. 5A-5C illustrate exemplary configurations for cooling stations according to some embodiments of the present invention. In FIG. 5A, a cooling station 560 is coupled next to a sputter deposition station 540 which comprises a target assembly 510. The cooling station can comprise a cooling support 550, which can regulate the temperature of the substrate 530 before being transferred to the deposition station 540. Alternatively, or additionally, the cooling station 560 can comprise a spray assembly 570 for spray cooling the substrate, for example, by spraying cold air or dry ice on the surface of the substrate.

In FIG. 5B, a cooling station 562 comprises cooling rollers 565 having circulated coolant 575 to maintain the rollers at a constant temperature. The substrate 530 can stop at the cooling station until reaching a desired temperature. Alternatively, the substrate can be cooled by passing through the cooling rollers. In addition, the deposition station 540 can also comprise cooling rollers for cooling the substrate.

In FIG. 5C, a cooling station 564 is disposed at an entrance of the deposition station 540, thus can lower the substrate temperature during the transferring of the substrate to the deposition station. The cooling station 564 can comprise a cold shower curtain 572, for example, spraying cold air or dry ice to the substrate 530.

Other embodiments can also be used, for example, a cooling station exposing the substrate to atmospheric environment for reaching the ambient temperature. Further, the present figures comprise simplified schematic, and thus various components are not shown, for example, optional vacuum environment for vacuum deposition station 540.

In some embodiments, the present invention discloses cooling an article between two sputter deposition processes. Sputter deposition employs plasma ambient, which can heat up the article and affect the quality of the subsequently deposited layer. For example, in a coated article used for low emissivity panel, multiple layers can be successively deposited, potentially raise the temperature of the article to above about 30 or about 40° C., from the original room temperature. The small temperature difference can affect the quality of the silver layer (or the seed layer for the silver layer), for example, raising the resistance of the deposited silver layer from about 7.7Ω to about 12.5Ω. In some embodiments, the article is cooled between layer depositions to achieve high quality sputtered layers.

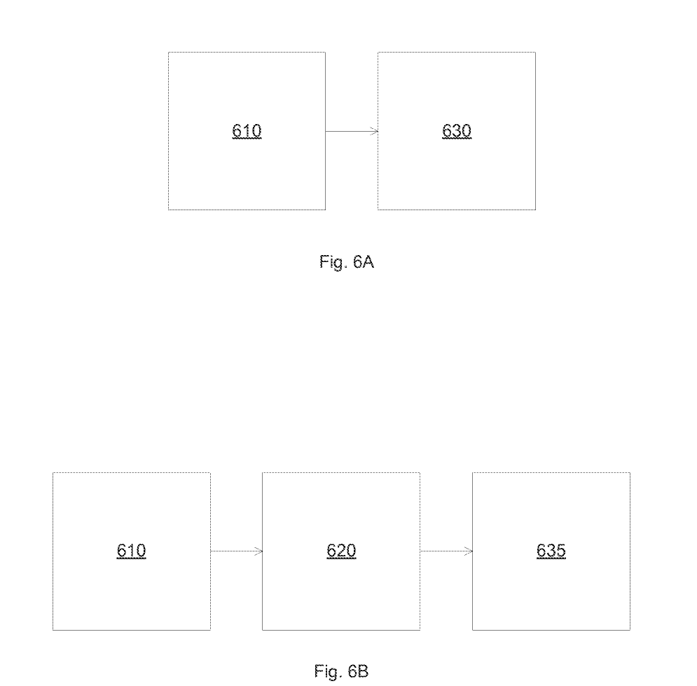

FIGS. 6A-6B illustrate exemplary configurations of multiple depositions with cooling capability according to some embodiments of the present invention. FIG. 6A shows two consecutive deposition systems 610 and 630 in which the deposition system 630 comprises a cooling capability for cooling the substrate. FIG. 6B shows two consecutive deposition systems 610 and 635 having a cooling station 620 in between.

The cooling station between deposition systems can serve to optimize the coated layer quality. For example, after a substrate is sputtered deposited in system 610, the substrate temperature can be raised above room temperature, for example, between 5 and 40° C. depending on the original substrate temperature. This temperature increase can potentially affect the quality of the coated layer, especially for the thin conductive layer acting as an infrared reflective layer. Thus a cooling station disposed between the two deposition systems allows the substrate temperature to be controlled, such as maintaining at around room temperature or below.

In some embodiments, the present invention discloses methods for making low emissivity panels in large area coaters. A moving mechanism can be provided to move a substrate forward under one or more sputter targets, to deposit seed, infrared reflective layers, together with other layers. A cooling station can be positioned between the deposition systems to regulate, e.g., reducing the temperature increase of the substrate, helping to improve the quality of the deposited layer, especially at thin thickness.

In some embodiments, the present invention discloses systems for making a coated article with cooling capability. The system can comprise a transport mechanism to transport the article between chambers or stations, a cooling station for cooling the article, and one or more sputter deposition chambers for sputter depositing layers on the article. The cooling station is preferably disposed between the sputter deposition chambers, for example, to ensure a consistent temperature of the article before being deposited. The cooling station can be disposed before critical deposition process, such as a seed layer deposition or an infrared reflective layer deposition, for example, to ensure an optimal quality of the coated article.

In some embodiments, the present invention discloses apparatuses for making low emissivity panels, comprising a cooling station disposed between sputtered deposition stations, in which a moving mechanism can be included to provide an in-line large area coater system.

In some embodiments, the present invention discloses an in-line deposition system, comprising a transport mechanism for moving substrates between deposition stations. In some deposition stations, a collimator can be provided to generate highly smooth deposited films.

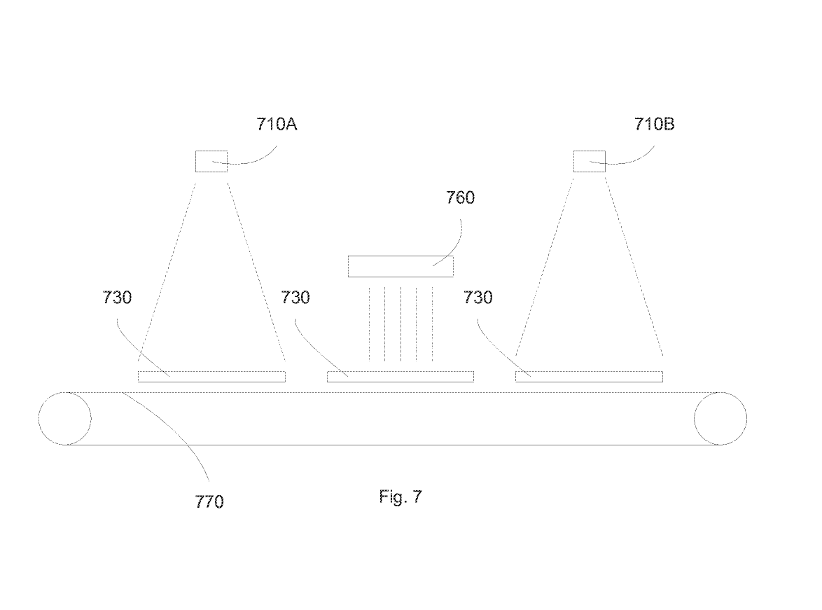

FIG. 7 illustrates an exemplary in-line deposition system according to some embodiments of the present invention. A transport mechanism 770, such as a conveyor belt or a plurality of rollers, can transfer substrate 730 between different sputter deposition stations. For example, the substrate can be positioned at first deposition station, comprising a target assembly 710A, then transferred to cooling station, comprising cooling assembly 760, and then transferred to second deposition station, comprising target assembly 710B. After the deposition in the first deposition station, the substrate can be heated up, thus the cooling station can restore the temperature of the substrate back to the original temperature before transferring the substrate to the second deposition station.

Other configurations can be used, such as cooling plate for cooling station. In addition, other stations can be included, such as input and output stations, or anneal stations.

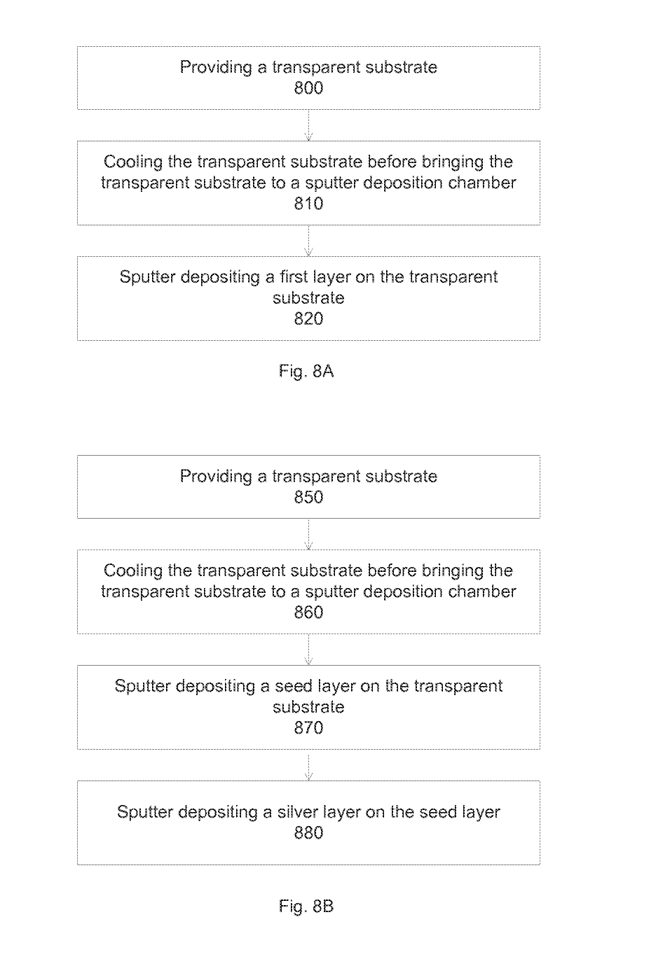

FIG. 8 illustrates a flow chart for sputtering coated layers according to some embodiments of the present invention. In FIG. 8, a substrate is cooled before being transferred to a deposition chamber. In operation 800, a transparent substrate is provided. The transparent substrate can include an antireflective layer, e.g., a layer having index of refraction between those of the transparent substrate and air, and/or a seed layer, e.g., a layer having crystal orientation that can promote the desired crystal orientation for the subsequently-deposited infrared reflective layer. In operation 810, the transparent substrate is cooled before being brought to a sputter deposition chamber. The cooling action can bring the substrate temperature to around room temperature or less, which can improve the quality of the deposited layer in the deposition chamber. For example, the cooling action can bring the substrate to a temperature between 5 C and 25 C, or between 10 C and 25 C. Alternatively, the cooling action can reduce the temperature of the substrate, for example, by an amount between 5 C and 25 C, or between 10 C and 25 C. In operation 820, a first layer is deposited over the transparent substrate in the deposition chamber. Since the temperature of the substrate is controlled by the cooling step, the quality of the first layer can be improved. The first layer can include a seed layer or an infrared reflective layer.

In some embodiments, the transparent substrate can include a layer having index of refraction between those of the transparent substrate and air. The layer can functioned as an antireflective layer to reduce the reflection of the incoming light. The substrate can be cooled before depositing subsequent layers, such as a seed layer of ZnO having (002) crystal orientation to promote a (111) crystal orientation of silver. An optional cooling step can be performed after the deposition of the seed layer. A layer of silver then can be deposited on the seed layer.

In some embodiments, the transparent substrate can include a seed layer, such as a layer of ZnO having (002) crystal orientation. A conductive layer can be deposited over the seed layer. The conductive layer can include an infrared reflective layer having silver, and having a surface crystal orientation that can be promoted by the surface crystal orientation of the seed layer. In some embodiments, other layers can be included, such as a protective layer, an oxide layer, a barrier layer, an antireflective oxide, an optical filler layer, an interface layer and an adhesion layer. The additional layer can be sputtered deposited through a collimator to reduce roughness.

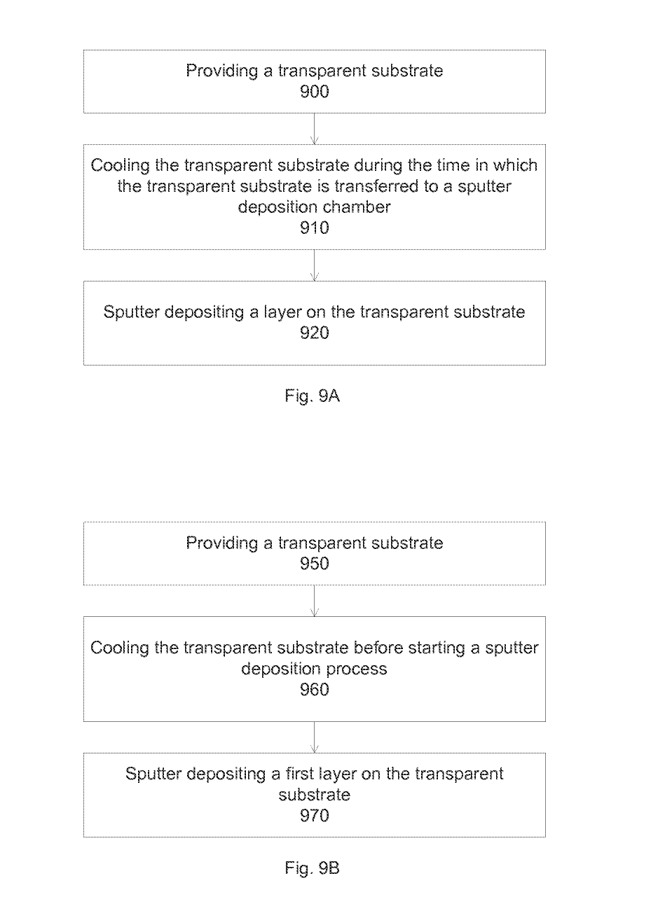

FIGS. 9A-9B illustrate other exemplary flow charts for sputtering coated layers according to some embodiments of the present invention. FIG. 9A shows a general exemplary method, comprising cooling a substrate during the transition time to a sputter deposition chamber. In operation 900, a transparent substrate is provided. The transparent substrate can include an antireflective layer, e.g., a layer having index of refraction between those of the transparent substrate and air, and/or a seed layer, e.g., a layer having crystal orientation that can promote the desired crystal orientation for the subsequently-deposited infrared reflective layer. In operation 910, the transparent substrate is cooled, e.g., by lowering the temperature of the substrate to a predetermined temperature or by a certain value. The substrate is cooled during the time in which the substrate is transferred to a sputter deposition chamber. For example, a cold air shower curtain can be used to spray cooling the substrate during the substrate movement. The cooling mechanism is performed during the movement of the substrate, thus minimizing throughput loss. In operation 920, a layer is sputtered deposited over the transparent substrate. The layer can include a seed layer, to be deposited over an antireflective layer on the substrate, or an infrared reflective layer, to be deposited over a seed layer on the substrate. With the cooled substrate, the layer can be thin and still possess optimal characteristics for a low emissivity panel.

FIG. 9B shows a general exemplary method, comprising cooling a substrate before sputter depositing a layer over the substrate surface. The substrate can be cooled outside the sputter deposition chamber, inside the deposition chamber, or during a transition time to the deposition chamber. In operation 950, a transparent substrate is provided. The transparent substrate can include an antireflective layer, e.g., a layer having index of refraction between those of the transparent substrate and air, and/or a seed layer, e.g., a layer having crystal orientation that can promote the desired crystal orientation for the subsequently-deposited infrared reflective layer. In operation 960, the transparent substrate is cooled, e.g., by lowering the temperature of the substrate to a predetermined temperature or by a certain value, before starting the process of sputter depositing a layer over the substrate. In operation 970, a layer is sputtered deposited over the transparent substrate. The layer can include a seed layer, to be deposited over an antireflective layer on the substrate, or an infrared reflective layer, to be deposited over a seed layer on the substrate.

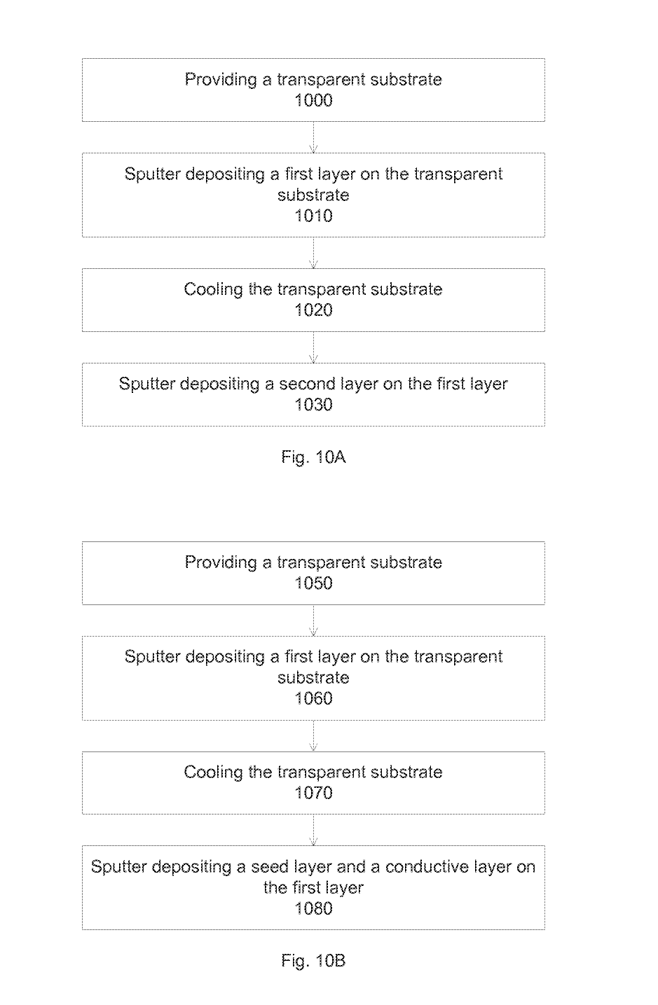

FIG. 10 illustrates another flow chart for sputtering coated layers according to some embodiments of the present invention. In FIG. 10, the substrate is cooled between successive sputter deposition steps. In operation 1000, a transparent substrate is provided. In operation 1010, a first layer is deposited over the transparent substrate in a first deposition chamber. The first layer can include a base layer, an antireflective layer, e.g., a layer having index of refraction between those of the transparent substrate and air, and/or a seed layer, e.g., a layer having crystal orientation that can promote the desired crystal orientation for the subsequently-deposited infrared reflective layer. In some embodiments, the substrate can be cooled to a predetermined temperature before depositing the first layer. In operation 1020, the transparent substrate is cooled before starting a second sputter deposition step. For example, the substrate can be cooled during a transition to a second deposition chamber, or can be cooled at the second deposition chamber before starting the second deposition step. In operation 1030, a second layer is deposited over the first layer in the second deposition chamber. The second layer can include an antireflective layer, to be deposited over the base layer, a seed layer, to be deposited over the antireflective layer, or an infrared reflective layer, to be deposited over the seed layer. The cooling step can reduce or regulate the temperature of the substrate, which can be increased due to the plasma heating during the deposition in the first deposition chamber.

In some embodiments, the first layer can include a base layer. The substrate can be cooled before depositing subsequent layers, such as a layer having index of refraction between those of the transparent substrate and air. The layer can functioned as an antireflective layer to reduce the reflection of the incoming light.

In some embodiments, the first layer can include a layer having index of refraction between those of the transparent substrate and air. The first layer can functioned as an antireflective layer to reduce the reflection of the incoming light. The substrate can be cooled before depositing subsequent layers, such as a seed layer of ZnO having (002) crystal orientation to promote a (111) crystal orientation of silver. An optional cooling step can be performed after the deposition of the seed layer. A layer of silver then can be deposited on the seed layer.

In some embodiments, the first layer can include a seed layer, such as a layer of ZnO having (002) crystal orientation. A conductive layer can be deposited over the seed layer. The conductive layer can include an infrared reflective layer having silver, and having a surface crystal orientation that can be promoted by the surface crystal orientation of the seed layer. In some embodiments, other layers can be included, such as a protective layer, an oxide layer, a barrier layer, an antireflective oxide, an optical filler layer, an interface layer and an adhesion layer. The additional layer can be sputtered deposited through a collimator to reduce roughness.

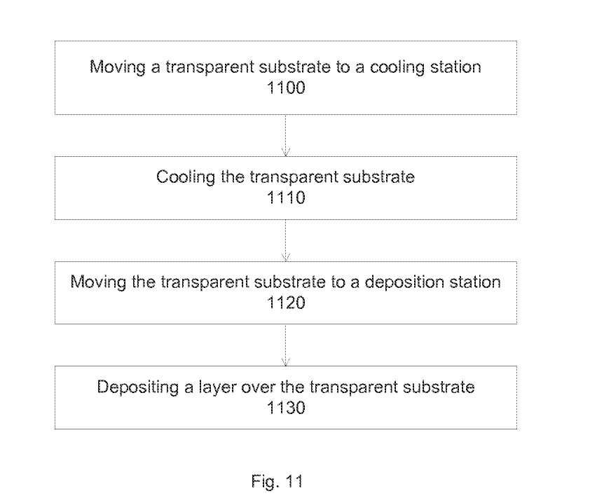

FIG. 11 illustrates another exemplary flow chart for sputtering coated layers according to some embodiments of the present invention. In operation 1100, a transparent substrate is moved to a cooling station, for example, by a transfer mechanism. In operation 1110, the substrate is cooled to a predetermined temperature or by a predetermined value. In operation 1120, the substrate is moved to a deposition station. In operation 1130, a layer is deposited over the substrate. The layer can be a seed layer, comprising a first surface crystal orientation to promote a second crystal orientation of a subsequently deposited conductive layer. A conductive layer can be deposited over the seed layer. The conductive layer can comprise an infrared reflective layer comprising silver. In some embodiments, other layer can be included, such as a protective layer, an oxide layer, a barrier layer, an antireflective oxide, an optical filler layer, an interface layer and an adhesion layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for making a coated article, the method comprising
providing a transparent substrate,
wherein the substrate comprises a first layer,
wherein the first layer comprises at least one of
an index of refraction between those of the transparent substrate and air, and
a crystal orientation enabling an (111) crystal orientation of silver;
cooling the transparent substrate before bringing the transparent substrate to a sputter deposition chamber;
sputter depositing a second layer on the first layer.

2. A method as in claim 1 wherein the second layer comprises a ZnO or a metal alloy layer.

3. A method as in claim 1 wherein the second layer comprises a silver layer.

4. A method as in claim 1 wherein the second layer comprises a seed layer for a silver layer, and wherein the method further comprises
sputter depositing a third layer comprising silver on the second layer.

5. A method as in claim 1 wherein the first layer comprises an antireflection layer.

6. A method as in claim 1 further comprising
sputter depositing a fourth layer on the second layer, wherein the fourth layer comprises a barrier layer.

7. A method as in claim 1 wherein the transparent substrate is cooled to a temperature of between 10° C. and 25° C.

8. A method as in claim 1 wherein the temperature of the cooled transparent substrate is lower between 5° C. and 25° C. relative to the temperature of the substrate before reaching the sputter deposition chamber.

9. A method for making a coated article, the method comprising
providing a transparent substrate;
sputter depositing a first layer on the transparent substrate,
wherein the first layer comprises at least one of
an index of refraction between those of the transparent substrate and air, and
a crystal orientation enabling an (111) crystal orientation of silver;
cooling the transparent substrate, after sputter depositing the first layer, to lower the temperature of the transparent substrate between 5 to 25° C.;
sputter depositing a second layer on the cooled transparent substrate.

10. A method as in claim 9 wherein the transparent substrate is cooled to a temperature of between 10° C. and 25° C.

11. A method as in claim 9 wherein the transparent substrate is cooled within a sputter deposition chamber that performs the sputter deposition of the second layer.

12. A method as in claim 9 wherein the transparent substrate is cooled during a transfer to a sputter deposition chamber that performs the sputter deposition of the second layer.

13. A method as in claim 9 wherein the transparent substrate is cooled outside a sputter deposition chamber that performs the sputter deposition of the second layer.

14. A system for making a coated article, the system comprising
a transport mechanism for transporting a substrate;
a cooling station for cooling the substrate;
a first sputter deposition chamber for sputter depositing a first layer on the substrate,
wherein the first layer comprises at least one of
an index of refraction between those of the transparent substrate and air,
a crystal orientation enabling an (111) crystal orientation of silver,
a silver material;
wherein the transport mechanism transfers the substrate from the cooling station to the first sputter deposition chamber.

15. A system as in claim 14 wherein the first sputter deposition is operable to deposit a ZnO or a metal alloy layer.

16. A system as in claim 14 wherein the first sputter deposition is operable to deposit a silver layer.

17. A system as in claim 14 further comprising
a second sputter deposition chamber for sputter depositing a second layer on the first layer,
wherein the transport mechanism transfers the substrate from the first deposition chamber to the second sputter deposition chamber.

18. A system as in claim 14 further comprising
a third sputter deposition chamber for sputter depositing a third layer on the substrate,
wherein the transport mechanism transfers the substrate from the third deposition chamber to the cooling station.

19. A system as in claim 14 wherein the cooling station is operable to cool the substrate to a temperature of between 10° C. and 25° C.

20. A system as in claim 14 wherein the cooling station is operable to lower the temperature of the substrate to a temperature of between 5° C. and 25° C. relative to the temperature of the substrate before reaching the sputter deposition chamber.
